(19) United States
(12) Patent Application Publication
(10) Pub. No.: US 2013/0104965 A1
(43) Pub. Date: May 2, 2013

(54) SOLAR CELL MODULE AND MANUFACTURING METHOD THEREFOR

(71) Applicants: Tobias Jarmar, Uppsala (SE); Lars Stolt, Uppsala (SE); Peter Neretnieks, Taby (SE)

(72) Inventors: Tobias Jarmar, Uppsala (SE); Lars Stolt, Uppsala (SE); Peter Neretnieks, Taby (SE)

(73) Assignee: SOLIBRO GMBH, Bitterfeld-Wolfen (DE)

(21) Appl. No.: 13/701,757

(22) PCT Filed: May 27, 2011
(86) PCT No.: PCT/DE11/75121

§ 371 Date: Jan. 22, 2013

(30) Foreign Application Priority Data
Jun. 4, 2010 (DE) 10 2010 017 246.4

(51) Int. Cl. H01L 31/042; H01L 31/18

(52) U.S. Cl. CPC H01L 31/0422; H01L 31/18
USPC 136/249; 438/64

(57) ABSTRACT

The invention relates to a solar cell module and to a manufacturing method for the same, the solar cell module comprising a glass carrier (1) and a solar cell structure (2) arranged on a device side surface (11) of the glass carrier (1), characterized by a protection layer (3) arranged on a back side surface (12) of the glass carrier (1) opposite to the device side surface (11).

The invention relates to a solar cell module comprising a glass carrier and a solar cell structure arranged on a device side surface of the glass carrier, and to a manufacturing method for such a solar cell module.

Such solar cell modules are gaining popularity due to their lower material cost compared to solar cells made of semiconductor wafers. Usually, the device side surface of the glass carrier is covered by solar cell structures, which are then enclosed and sealed by a glass cover to protect them from external influences. The solar cell structures generally comprise a metal layer, often made of molybdenum, deposited directly on the glass carrier as a back electrode, followed by a semiconductor stack acting as a photovoltaic active structure and finally by a further conducting layer as a front electrode. The front electrode is usually made of a transparent conducting material in order to allow incident light to pass through.

Glass usually acts as a good protecting and sealing material for the solar cell structures. However, it has been shown that after time the solar cell efficiency decreases notably. Especially during climate testing and certificate testing, when the solar cell modules are subjected to extensive heat and/or humidity, the degradation of the solar cells is quite significant.

It is an object of the invention to reduce or even prevent such degradation in order to keep the solar cell efficiency fairly constant even after many years of use.

The object is achieved in this invention by providing a solar cell module with the features of claim 1, and a manufacturing method for solar cells with the features of claim 15. Advantageous embodiments of the invention are subject of the sub-claims.

The invention is based on the discovery that the loss of efficiency of known solar cell modules is due to a degradation of the glass carrier. In a humid environment, a back side surface of the glass carrier opposite to the device side surface becomes laterally conductive. A potential difference between this back side surface and the back electrode of the solar cell on the device side surface leads to an electric field to develop across the glass carrier. This electric field drives ions, in particular sodium ions, to travel through the glass carrier to the back electrode of the solar cell. The ions react with the material of the back electrodes, leading to a degradation of its function.

To alleviate this effect, it is suggested to arrange a protection layer on the back side surface of the glass carrier. The protection layer may help to reduce the ion flow by reducing or even preventing the build-up of the electric field across the glass carrier. This may be achieved either by adjusting the surface potential on the back side surface of the glass carrier. For this approach, the protection layer may be made of a conductive material such as a metal, to act as an equipotential surface, to which an arbitrary voltage may be applied in order to counteract the electric field.

In an alternative approach, the protection layer may be designed such that a lateral conductivity of the back side surface is prevented even in humid and hot environments. This may be achieved by using an isolating tape, a dielectric layer, paint or other layers or foils of suitable non-conductive materials for making the protection layer.

When manufacturing such a solar cell module, the protection layer may be applied to the back side surface of the glass carrier any time during the manufacturing process, i.e. before or after the deposition of the solar cell structure, or even in-between process steps for the deposition of the solar cell structure. Advantageously, the glass carrier may be delivered to the solar module manufacturing site with a pre-deposited protection layer on its back side surface.

In an advantageous embodiment, the solar cell structure is a thin film solar cell structure monolithically deposited onto the device side surface of the glass carrier. The monolithic manufacture of the solar cell structure on the glass carrier has the advantage that there is an innate connection between the glass carrier and the solar cell structure. In other words, the solar cell structure is deposited layer by layer onto the glass carrier. The opposite to a monolithic deposition would be producing the solar cell structures separately from the glass carrier, and arranging them onto the glass carrier afterwards. For example, the glass cover, placed onto the monolithic structure of solar cell on glass carrier for sealing the solar cells, is not connected monolithically to the solar cell structures.

Thin film solar cells may be based on amorphous silicon or other thin-film silicon structures, on cadmium telluride (CdTe), or on copper indium gallium selenide (CIS or CIGS), or they may comprise dye-sensitized (DSC) or other organic solar cells.

In a preferred embodiment, the glass carrier is a substrate for the solar cell structure. That means that the glass carrier is placed on the back side of the solar cell structure, opposite to the light incident side. Alternatively, the glass carrier may be a superstrate of the solar cell structure, in which case the incident light will have to pass through the glass carrier to reach the solar cell structure. In this latter case, the protection layer will have to be made of a transparent material.

In a preferred embodiment, the solar cell structure of the solar cell module to be protected from degradation comprises a metal layer in direct contact with the device side surface of the glass carrier. The metal layer may in particular be made of molybdenum.

In an embodiment with a minimized protection layer surface area, a surface area on the back side surface corresponding to a device side surface area covered by the solar cell structure is covered essentially completely by the protection layer. Here, the expression “corresponding” means that the device side surface area covered by the solar cell structure is projected onto the back side to obtain the surface area covered by the protection layer. Thus, at least the area on the back side surface directly adjacent to the solar cell structure is covered by the protection layer in order to discourage an electric field build-up immediately below the solar cell structure.

However, to better protect the solar cell module, it is advantageous that the protection layer covers essentially the entire back side surface of the glass carrier. This embodiment has the added advantage that the protection layer on the back side surface need not be patterned and that the solar cell structure and the protection layer do not need to be aligned to each other.

As mentioned above, in one alternative embodiment of the solar cell module, the protection layer is made of a conductive material for applying a constant potential to the back side surface of the glass carrier. The protection layer may for example be made of a metal or of a conductive oxide. Such a conductive protection layer allows for a predetermined or regulated potential to be applied to the back side surface of the glass carrier in order to counteract any potential difference between the device side surface and the back side surface.

As also described above, the protection layer is, in a different alternative embodiment, made of a non-conductive material. In particular, the protection layer in this embodiment has preferably a sheet resistance of at least 10¹² ohms per square, more preferably of least 2×10¹², 5×10¹², or 10¹³ ohms per square.

Advantageously, the protection layer comprises a layer of paint applied to the back side surface of the glass carrier. Good results have for example been obtained with the use of so called truck paint. The protection layer may, for example, comprise a polyvinyl butyral based primer with an epoxy resin. Such a material may be used alone or as an underlying layer for paint. The paint itself may be polyurethane based, with an addition of pigments if required.

Depending on the manufacturing method and/or the utilized material, the protection layer may be amorphous, nanocrystalline, polycrystalline or monocrystalline. The expression nanocrystalline may also be referred to as microcrystalline, while the expression monocrystalline may also be referred to as single-crystalline.

In preferred embodiments, the protection layer comprises an oxide, a nitride and/or an oxynitride. Alternatively, the protection layer may be a polymer tape, a paint such as a photoresist, or a film of other suitable material. The protection layer may be either deposited onto the back side surface or applied to it by any other suitable means, such as by a printing method.

In a preferred embodiment, the protection layer is made of aluminum oxide, silicon oxide, silicon nitride, silicon oxynitride, aluminum oxynitride, silicon aluminum oxynitride or of a compound of one of these materials and one or more further elements. Other suitable materials, in particular conductive materials such as conductive transparent oxides, may be used as well, such as Zn₂SnO₄.

In particularly advantageous embodiment, the protection layer is a humidity barrier. In an alternative embodiment, or in addition, a surface of the protection layer facing away from the glass carrier is hydrophobic. Here, the entire protection layer may be made of a hydrophobic material, or the surface of the protection layer may be made hydrophobic by surface treatment. This embodiment is especially useful for non-conductive protection layers, since an undesirable rise in conductivity due to humidity accumulation may be averted. However, the feature of being hydrophobic may also be advantageous for already conductive protection layers, in order to prevent any humidity to reach the glass carrier surface.

It should be noted that even a thin layer of silicon oxide deposited onto a glass carrier, which is made of silicon oxide itself, may be able to act as an effective protection layer. Since only a small amount will be needed for the deposition of the protection layer compared to the amount needed for manufacturing the glass carrier, the former can be produced at a much higher quality and with a chosen set of chemical and physical characteristics optimized for the purposes described above.

The protection layer may preferable have a layer thickness of more than 25 nm, preferably between 25 and 500 nm, although thicker layers may be suitable as well. The protection layer according to any herein mentioned embodiment may be deposited via physical or chemical vapor deposition (PVD or CVD), which may be plasma supported (PECVD). Other deposition methods may be used as well, such as sputtering or epitaxial deposition methods.

An example of an embodiment of the invention will be explained in more detail in the following description with reference to the accompanying schematic drawings, wherein

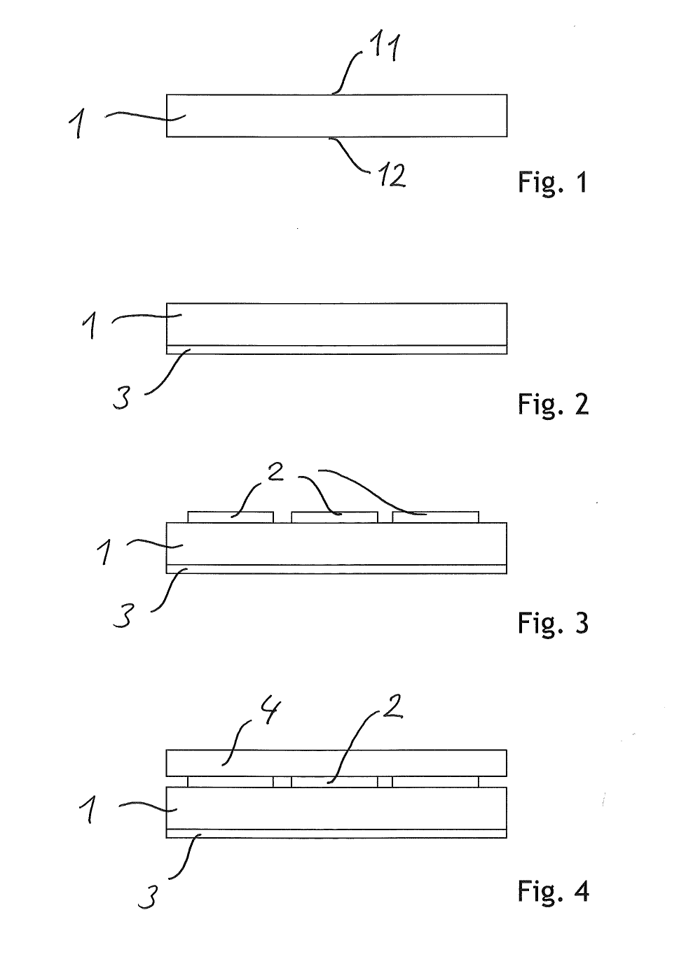

FIG. 1 shows a glass carrier;

FIG. 2 shows the glass carrier of FIG. 1 covered by a protection layer;

FIG. 3 shows solar cell structures formed on the glass carrier; and

FIG. 4 depicts a solar cell module comprising the solar cell structures sandwiched between the glass carrier and a glass cover.

The FIGS. 1 to 4 illustrate different stages in the manufacture of a solar cell module according to a preferred embodiment. As shown in FIG. 1, first a glass carrier 1 of suitable size and thickness is provided, comprising a device side surface 11 and a back side surface 12.

As shown in FIG. 2, the back side surface 12 of the glass carrier 1 is covered substantially completely by a protection layer 3, for example made of silicon oxide (SiO₂), with a layer thickness of approximately 25 nm or higher. However, producing a layer thickness of much more than 500 nm may be too expensive compared to any advantages the higher thickness may provide. The glass carrier 1 may already be provided with the protection layer 3 when delivered to the solar cell manufacturing site.

Afterwards, as shown in FIG. 3, solar cell structures 2 are produced on the device side surface 11 of the glass carrier 1, comprising a number of layers deposited onto the glass carrier 1. Any solar cell structure 2 produced as thin film solar cells may be suitable for this purpose. Finally, as depicted in FIG. 4, a cover glass 4 is placed upon the solar cell structures 2, to protect them while at the same time allowing incident light to pass through the cover glass 4 to be transformed to electrical energy in the solar cell structures 2.

While in the manufacturing process described herein, the protection layer 3 is deposited onto the back side surface 12 of the glass carrier 1 before producing the solar cell structures 2, the process may be reversed instead, or alternatively the protection layer 3 may be deposited in-between deposition steps of the solar cell structures 2. Later on, the solar cell module may be sealed along the edges and placed in a frame for support.

### REFERENCE NUMERALS

1 glass carrier

11 device side surface

12 back side surface

2 solar cell structure

3 protection layer

4 cover glass

1-17. (canceled)

18. Solar cell module comprising a glass carrier and a solar cell structure arranged on a device side surface of the glass carrier, wherein a protection layer is arranged on a back side surface of the glass carrier opposite to the device side surface, wherein the protection layer comprises a layer of paint and/or an isolating tape.

19. Solar cell module according to claim 18, wherein the solar cell structure is a thin film solar cell structure monolithically deposited onto the device side surface of the glass carrier.

20. Solar cell module according to claim 18, wherein the glass carrier is a substrate for the solar cell structure.

21. Solar cell module according to claim 18, wherein the solar cell structure comprises a metal layer in direct contact with the device side surface of the glass carrier.

22. Solar cell module according to claim 21, wherein the metal layer in contact with the device side surface is made of molybdenum.

23. Solar cell module according to claim 18, wherein a surface area on the back side surface corresponding to a device side surface area covered by the solar cell structure is covered essentially completely by the protection layer.

24. Solar cell module according claim 23, wherein the protection layer covers essentially the entire back side surface of the glass carrier.

25. Solar cell module according to claim 18, wherein the protection layer is made of a non-conductive material.

26. Solar cell module according claim 25, wherein the protection layer has a sheet resistance of at least 10¹² ohms per square.

27. Solar cell module according to claim 18, wherein the protection layer is a humidity barrier.

28. Solar cell module according to claim 18, wherein a surface of the protection layer facing away from the glass carrier is hydrophobic.

29. Manufacturing method for a solar cell module, comprising the following steps:
providing a glass carrier;
depositing a solar cell structure onto a device side surface of the glass carrier; and
applying a protection layer, which comprises a layer of paint and/or an isolating tape, onto a back side surface of the glass carrier opposite to the device side surface.
